(19) United States
(12) Patent Application Publication
(10) Pub. No.: US 2005/0008871 A1
(43) Pub. Date: Jan. 13, 2005

(54) Method for coating and/or partial extrusion-coating of flexible, elongated products

(76) Inventor: Manfred Sikora, Wipperfurth (DE)

Correspondence Address: BIRCH STEWART KOLASCH & BIRCH, PO BOX 747, FALLS CHURCH, VA, 22040-0747, US

(21) Appl. No.: 10/885,652

(22) Filed: Jul. 8, 2004

(30) Foreign Application Priority Data
Jul. 12, 2003 (DE) 103 31 608.6

(51) Int. Cl. C08J 7/18; C23C 16/00; B32B 27/00

(52) U.S. Cl. 428/421; 427/532; 427/248.1; 428/492

(57) ABSTRACT

In order to coat and/or partially extrusion-coat flexible, elongated products, such as electrical cables or wires, and also pipes, tubing or hoses, whose surface has a material-conditioned nonstick characteristic, such as polytetrafluoroethylene, the surface of the product is wholly or partially activated (structured) through a plasma treatment and then flowable materials are applied to the activated (structured) surface area under the influence of heat and/or pressure as a coating, with complete or partial coverage, or as a formed part.

This nonprovisional application claims priority under 35 U.S.C. § 119 (a) on German Patent Application No. 103 31 608.6 filed in Germany on Jul. 12, 2003, which is herein incorporated by reference.

### BACKGROUND OF THE INVENTION

1. Field of the Invention

The present invention relates to a method for coating and/or partial extrusion-coating of flexible, elongated products, such as electrical cables or wires, and also pipes, tubing or hoses, whose external surface has a material-conditioned nonstick characteristic.

2. Description of the Background Art

Materials with nonstick behavior are, for example, fluorinated polyolefin-based polymers, such as polytetrafluoroethylene, which are also used to a great extent in cable and wire engineering. In order to create tension-proof, pressure-tight and moisture-proof connection points, termination points or splice points in electrical cables or wires encased in such materials, it is already known (DE-PS 30 41 657) to push a formed part made of a melt processable fluoropolymer with a lower melting point over the cable or wire at the applicable point and to arrange over this a second formed part made from a material corresponding to the sheathing.

The application of heat and pressure melts the first formed part, the melt fills the space enclosed by the second formed part and simultaneously effects a mechanically strong connection between the sheathing of the cable or wire and the inner surface of the second formed part. In the manufacture of splicing sleeves and terminations for cables and wires, such as for the prefabrication thereof, additional materials from the same polymer family, but with different melting characteristics, are used here.

The use of melt processable fluoropolymers for the secure connection of polytetrafluoroethylene with other materials has also already found favor in cable manufacture itself. Thus, it has been known (DE-OS 44 14 052) to join the metallic conductor of an electrical cable firmly to the cable insulation of a porous polytetrafluoroethylene with the aid of an extrudable fluoropolymer, such as a tetrafluoroethylene/hexafluoropropylene copolymer (FEP).

A known mechanical push-pull cable (Bowden cable) (EP PS 692 25 502) exhibits a similar structure, in which a sheathing of polytetrafluoroethylene, with its low coefficient of friction, is joined to the inner steel core by an extruded fluoropolymer layer.

However, melt processable fluoropolymers, such as fluorinated ethylene propylene (FEP) or a perfluoroalkoxy polymer (PFA), have also already been used (EP PS 07 48 509) for adhering the insulation of a high frequency coaxial cable made of polytetrafluoroethylene to the shielding arranged over the insulation.

This discussion of the prior art makes it clear that regardless of the particular application, the very pronounced nonstick behavior and the high melting viscosity of polytetrafluoroethylene make for problems when structural elements of this material are to be mechanically joined permanently to elements made of other materials. The low surface tension, e.g. of polytetrafluoroethylene (PTFE), has the result that the PTFE surface cannot be wetted by adhesives, for example, and hence adhesion cannot be attained. On the other hand, heat welding of PTFE using the techniques customary for plastics fails due to the aforementioned high melting viscosity.

### SUMMARY OF THE INVENTION

It is therefore an object of the present invention to provide a possibility for preparing elongated, flexible products with characteristic nonstick behavior such that mechanical joining with any other desired materials can be achieved without difficulty.

This object is attained in accordance with the invention in that the surface of the product is wholly or partially activated through a plasma treatment and then flowable materials are applied to the activated surface area under the influence of heat and/or pressure as a coating, with complete or partial coverage, or as a formed part. In a departure from the prior art, it is possible using this method to injection mold a termination or connection part, for example made of a thermoset plastic, directly onto the polytetrafluoroethylene insulation of an electrical cable so that its placement is permanent without the need for any intermediate layers. As tests have shown, the invention results in particular advantages in the prefabrication of cables, wires, pipes, tubing or hoses.

Plasma treatment of formed parts made of materials with nonstick behavior is already known per se (DE PS 198 34 065). This known process relates to the manufacture of a shaft seal with a component having a support and a connecting part made from a fluorocarbon whose surface has been activated by plasma treatment. Unlike the invention, however, this does not relate to the coating of elongated flexible products, but to the joining together of formed parts. This also applies to the prior art cited in this document; the distinction here resides solely in the type of plasma treatment.

While it is true that cord-like product has already been exposed to the effects of a plasma in a continuous process (DE OS 101 49 834), unlike the invention this has been for the purpose of applying a coating from the plasma onto the material passing through.

A further solution to the object of the invention, for the purpose of coating elongated products with a metallic material, is to fully or partially activate the surface of the product through plasma treatment and then to vapor deposit the metallic materials onto the activated surface region as a coating with complete or partial coverage. This method is especially advantageous when the metallic layer serves as shielding, for example, for a high frequency coaxial electrical cable.

It can also be advantageous to follow the plasma treatment for activating or structuring the surface having material-conditioned nonstick characteristics by incorporating foreign molecules contained in the process gas into the surface in the activated/structured area of the surface. For example, a surface structured or activated by oxygen can then be exposed to a process gas containing silane. As a result of the silane molecules that are, so to speak, grafted onto the already activated surface, there arises here an additional propensity for the surface of the product to adhere to other types of materials, for example elastomers. The modification of the boundary layer between two layers to be joined is not comparable to an adhesive layer, thus it is not a so-called hot melt adhesive, which would be applied to the surface of the product as a separate layer.

To carry out the method according to the invention, a wide variety of plasma treatment methods may be used, such as those described in the prior art. At present, however, the best results are achievable with a so-called low pressure plasma treatment in which the surface of the elongated product is activated by a plasma treatment at a pressure of approximately 0.1 to 1 mbar (DE PS 198 34 065).

In carrying out the invention, the plasma treatment of the nonstick surface of the product is performed continuously or discontinuously, depending on the length of the product. In the case of continuous plasma treatment, such as for the purpose of a subsequent coating of the product over its entire length, the product is usefully passed through at least one plasma unit with at least one chamber, in which the process gas is introduced and the plasma is generated from the gas. Such a unit can, for example, be structured such that the product is passed by at least one chamber in which the process gas is introduced, the plasma is then generated therefrom, and subsequently the plasma is delivered out of the chamber to the surface of the product.

So that delivery of the plasma takes place over the entire circumferential surface of the product, ring nozzles may be used, but in order to avoid so-called shadow formation during reeling of the treated product, it is also possible to have a take-up device, for example, a winding reel, rotate in an axial direction.

An especially advantageous field of application for the invention is a prefabrication of an elongated product, in particular of electrical cables or wires. In this context, any desired formed parts with a wide variety of functions are placed on the ends of the cables or wires, wherein an extremely good, mechanically strong, and moisture-proof connection between the cable or wire surface and the formed part is critical. In such cases, it has proven especially advantageous to place the elongated product of a defined length in a chamber in the form of a drum, which rotates during the plasma treatment after introduction of the process gas. If short lengths of the product are involved, for example 30 cm in length, the products may also be placed in the drum as loose product. For greater lengths, it is useful for the product to be wound into rings which are placed in rotation additional to the rotation of the drum to avoid shadow formation during plasma treatment.

In addition to silicone rubbers, for example, with an especially pronounced nonstick characteristic are well known to include fluoropolymers, and among these polytetrafluoroethylene, in particular. The present invention enables the mechanically strong, pressure-tight and moisture-proof connection of dissimilar materials, such as thermoset plastics, elastomers, thermoplastics, or thermoplastic rubbers, to the fluoropolymers under discussion in a continuous production process. The dissimilar materials can have an insulating effect, they can be coloring pigments, but they can also contain carbon black and consequently be conductive.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic illustration of a continuous plasma treatment of an electrical cable;

FIG. 2 is a schematic illustration of a plasma treatment process for short length product;

FIG. 3 is a schematic illustration of an electrical wire according to a preferred embodiment of the invention; and

FIG. 4 is a schematic illustration of an electrical wire according to an alternate embodiment of the invention.

### DETAILED DESCRIPTION

In a low pressure plasma process, preferentially used in accordance with the invention for the activation/structuring of the nonstick surface of cord-like product, a vacuum of 0.1 to 1.0 mbar is produced in a closed chamber and the so-called process gas, for example oxygen, hydrogen, argon, or argon/hydrogen, or the like, is introduced. The gas is ionized in a high frequency electric field, and the chosen cord-like product is subjected to the plasma thus produced. During the process, gas which is already contaminated is drawn from the treatment chamber during the continuous feeding of new process gas. The electrical energy for producing the plasma can be supplied to the process gas from the outside of the chamber by microwaves, or by an electrode arrangement located within the chamber.

FIG. 1 shows schematically the continuous plasma treatment of an electrical cable 1. The cable core has an insulation made of a fluoropolymer, for example polytetrafluoroethylene (PTFE). In order to coat the PTFE insulation in this example embodiment with an outer sheath of a silicone rubber, the cable 1 is first subjected in a nozzle-like arrangement 2 to the action of a plasma unit 3 and the PTFE of the insulation is surface activated (structured) in the process. The insulation of the cable thus prepared is extrusion-coated with the silicone rubber in an extruder 4, either in a continuous process immediately thereafter, or else at a later point in time. After passage through a conventional cooling chute 5, the sheathed cable 1 can be reeled onto a feed drum 6.

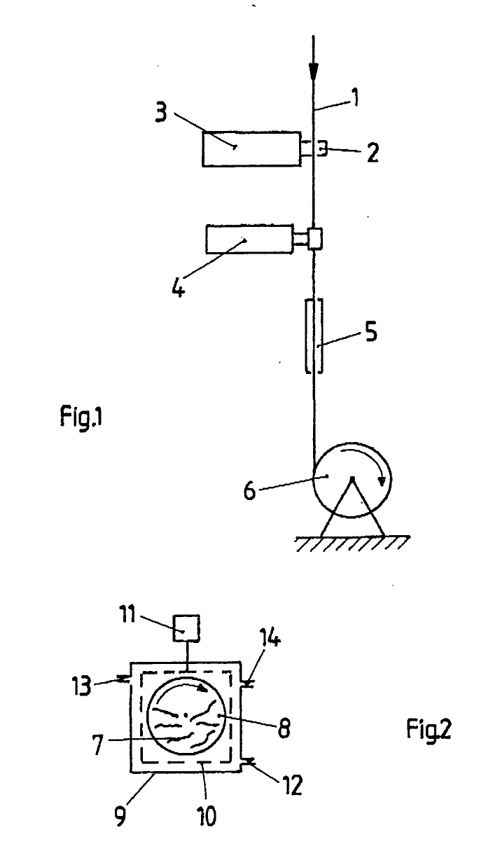

FIG. 2 shows schematically a plasma treatment process for short lengths of cord-like product. In this case, short lengths 7 of an electrical wire sheathed with PTFE or another fluoropolymer, or with another material with nonstick surface characteristics, for example a rubber, are placed in a drum 8 that can be closed to the outside. The wire ends have a length of 20 to 50 cm, for example, they are meant to be prefabricated, i.e. their ends are to be extrusion-coated with formed parts of any desired design to be mechanically strong, pressure-tight and moisture-proof.

The drum 8 is rotatably mounted in a chamber 9. An electrode 10, which is connected to a high frequency generator 11, surrounds the drum 8 on all sides for generating the treatment plasma. The chamber is evacuated through an outlet 12, and in so doing is set to a vacuum of 0.2 to 0.4 mbar. A connection element 13 is used for supplying the process gas, while the process gas itself, for example oxygen, is ionized under the influence of the high frequency electric field, generated by electrode 10 and HF generator 11, thus producing the treatment plasma, which is used to activate or structure the surfaces of the short lengths 7 with a nonstick character.

A chamber connection 14 serves to ventilate the interior space after conclusion of the treatment, but, after ventilation, can also be used to introduce a process gas or purge gas whose components of related material type to the formed part to be applied produce, under the influence of the electric field and the ionization effect, additional adhesion points on the wire surface that are activated or structured by oxygen or hydrogen, for example.

After the short lengths 7 have been removed from the drum 8, they can be subjected to a prefabrication process immediately, or at a later time. To do so, the ends of the short lengths 7, with or without additional adhesion points, are subjected to a processing step, while the e.g. elastic or thermoset plastic formed parts are applied to the wire ends in an injection mold.

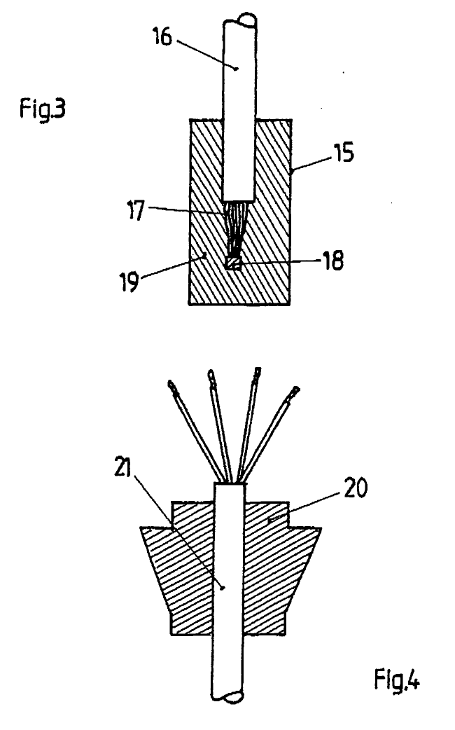

FIGS. 3 and 4 illustrate such embodiments of the invention. FIG. 3 shows a termination in the form of a thermoindicator 15 of an electrical wire 16 insulated with PTFE, in which the inventive concept is realized. Conductors 17 of the wire 16 are, as is customary in thermoindicators, brought together at the location 18, the moisture-proof and tension-proof encapsulation of the conductors 17 is accomplished by the formed part 19, which was molded directly onto the activated/structured surface of the polytetrafluoroethylene insulation of the wire 16 after activation of the surface by, for example, a plasma treatment with oxygen as the process gas. A thermoset plastic or also a rubber material, such as a silicone rubber, are examples of a suitable material that may be used for this.

Unlike FIG. 3, FIG. 4 shows a cable inlet in which a formed part 20 has been molded onto the surface, which was activated at least in this region, of a four-conductor cable 21 sheathed with a silicone rubber in an injection molding process either immediately or after purging of the structured surface with a silanized process gas.

The proposal according to the invention of implementing a mechanically strong connection between the nonstick surface of fluoropolymers or other materials with the same or similar characteristics and dissimilar materials immediately or after a surface modification subsequent to activation, can be applied to the manufacture of plugs, couplings and the like, and in this regard the example embodiments are not intended to limit the invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A method for coating and/or partial extrusion-coating of flexible, elongated products, whose surface has a material-conditioned nonstick characteristic, the method comprising:
activating at least a portion of the surface of the product by a plasma treatment; and
applying flowable materials to the activated surface area under the influence of heat and/or pressure as a coating, with complete or partial coverage, or as a formed part.

2. A method for coating and/or partial extrusion-coating of flexible, elongated products, whose surface has a material-conditioned nonstick characteristic, the method comprising:
activating at least a portion of the surface of the product by a plasma treatment; and
vapor-depositing metallic materials on the activated surface area as a coating, with complete or partial coverage.

3. The method according to claim 1, wherein, subsequent to the plasma treatment, the activated surface having nonstick characteristics is modified by a component contained in the process gas or purge gas.

4. The method according to claim 3, wherein the activated surface is a boundary layer by which a mechanical joining of the coating or the formed part to the surface of the elongated product is accomplished.

5. The method according to claim 1, wherein a low pressure plasma technique is used for the plasma treatment.

6. The method according to claim 1, wherein the plasma treatment of the nonstick surface of the product is performed continuously or discontinuously, depending on the length of the product.

7. The method according to claim 6 wherein the plasma treatment is performed continuously, and wherein the elongated product passes through a plasma unit having at least one chamber, in which the process gas is introduced and the plasma is generated from the gas.

8. The method according to claim 7, wherein the elongated product is passed through the at least one chamber into which the process gas is introduced, whereby the plasma is generated therefrom, and subsequently the plasma is delivered out of the chamber to the surface of the product.

9. The method according to claim 8, wherein the plasma is completely distributed over a circumference of the elongated product.

10. The method according to claim 6 wherein the plasma treatment is performed discontinuously, and wherein the elongated product is placed in a drum, which rotates during the plasma treatment after introduction of the process gas.

11. The method according to claim 10, wherein short lengths of the product are placed as loose product in the drum and are then subjected to the plasma treatment.

12. The method according to claim 10, wherein the elongated product is placed as a wound ring in the drum and is then subjected to the plasma treatment.

13. The method according to claim 12, wherein the elongated product that is formed as a wound ring rotates within the drum in addition to the rotation of the drum to thereby avoid shadow formation on the surface of the elongated product.

14. The method according to claim 1, wherein the surface material of the elongated product having nonstick characteristics is a fluoropolymer.

15. The method according to claim 1, wherein the surface material of the elongated product having nonstick characteristics is a silicone rubber.

16. The method according to claim 1, wherein the elongated product has a limited length and one or both ends of the elongated product, having the activated surface, are extrusion-coated directly with a formed part made of dissimilar materials.

17. The method according to claim 16, wherein the dissimilar materials include thermoset plastics, elastomers, thermoplastics, or thermoplastic rubbers.

18. The method according to claim 1, wherein a layer enveloping the product is extruded directly onto the activated surface of the elongated product.

19. The method according to claim 18, wherein the enveloping layer is conductive.

20. The method according to claim 1, wherein the method is applied for a prefabrication of electrical cables and wires, pipes, tubing or hoses.

21. The method according to claim 1, wherein the flexible, elongated products include electrical cables, wires, pipes, tubing, or hoses.

22. The method according to claim 2( wherein the flexible, elongated products include electrical cables, wires, pipes, tubing, or hoses.

23. An elongated product comprising:
a surface having a nonstick characteristic that is at least partially activated by a plasma treatment; and
a coating being formed of a flowable material that is applied to at least a portion of the surface of the elongated product by a plasma treatment via heat or pressure.
